(19) United States
(12) Patent Application Publication
(10) Pub. No.: US 2024/0234390 A1
(43) Pub. Date: Jul. 11, 2024

(54) STACKED MICROELECTRONIC PACKAGE WITH STACK MOUNTED COMPONENTS AND RELATED METHODS, DEVICES, AND SYSTEMS

(71) Applicant: Micron Technology, Inc., Boise, ID (US)

(72) Inventors: Seng Kim Dalson Ye, Singapore (SG); Kelvin Tan Aik Boo, Singapore (SG); Hong Wan Ng, Singapore (SG); See Hiong Leow, Singapore (SG); Ling Pan, Singapore (SG)

(21) Appl. No.: 18/389,613

(22) Filed: Dec. 19, 2023

Related U.S. Application Data
(60) Provisional application No. 63/479,260, filed on Jan. 10, 2023.

(51) Int. Cl. H01L 25/16; H01L 23/498

(52) U.S. Cl. CPC H01L 25/16; H01L 23/49827; H01L 23/49833; H01L 24/48

(57) ABSTRACT

A microelectronic device package includes a stack of semiconductor dies positioned over a substrate. The microelectronic device package further includes an interposer structure coupled to the stack of semiconductor dies. The microelectronic device package further includes an electronic component directly coupled to the interposer structure and electrically coupled to the substrate through an electrical connection between the interposer structure and the substrate.

### CROSS-REFERENCE TO RELATED APPLICATION

This application claims the benefit under 35 U.S.C. § 119(e) of U.S. Provisional Patent Application Ser. No. 63/479,260, filed Jan. 10, 2023, the disclosure of which is hereby incorporated herein in its entirety by this reference.

### TECHNICAL FIELD

Embodiments of the present disclosure generally relate to stacked microelectronic packages. In particular, embodiments of the present disclosure relate to stacked microelectronic packages with stack mounted components and associated methods, devices, and systems.

### BACKGROUND

As a consequence of many factors, including demand for increased portability, computing power, memory capacity and energy efficiency, microelectronic devices such as semiconductor devices and packages comprising such devices, are continuously being reduced in size. The sizes of the constituent features (i.e., critical dimensions) that form the devices, e.g., circuit elements and interconnect lines, as well as the pitch between (i.e., spacing) structures are also constantly being decreased to facilitate this size reduction.

Microelectronic devices may be stacked, such as, in stacked semiconductor packages (e.g., 3-D integrated circuits) to increase one or more of a memory capacity and computing power of the resulting semiconductor device while still consuming less real estate (i.e., surface area) and facilitating signal speed and integrity. Stacked semiconductor packages may include a plurality of vertically stacked semiconductor dies. The semiconductor dies, in a stacked semiconductor die package, may be operably coupled together by conductive elements between aligned through-silicon vias (TSVs) of superimposed dies, direct contacts, or wire bonding.

A stacked microelectronic device may include different types of semiconductor packages stacked on one another. For example, a stacked semiconductor package, such as a memory stack (e.g., NAND stack) may be stacked over an application specific integrated circuit (e.g., ASIC or controller). The different semiconductor packages may be operatively coupled together through a substrate or through direct connections between the packages.

### BRIEF DESCRIPTION OF THE DRAWINGS

While the specification concludes with claims particularly pointing out and distinctly claiming embodiments of the present disclosure, the advantages of embodiments of the disclosure may be more readily ascertained from the following description of embodiments of the disclosure when read in conjunction with the accompanying drawings in which:

FIG. 1 illustrates a top-down view of a microelectronic device package in accordance with embodiments of the disclosure;

FIG. 2 illustrates a longitudinal cross-sectional view of a microelectronic package in accordance with one or more embodiments of the disclosure;

FIGS. 3 and 4 illustrate enlarged, longitudinal cross-sectional views of embodiments of an interposer of the microelectronic package illustrated in FIG. 2;

FIG. 5 illustrates a longitudinal cross-sectional view of a microelectronic package, in accordance with one or more embodiments of the disclosure;

FIG. 6 illustrates a longitudinal cross-sectional view of a microelectronic package, in accordance with one or more embodiments of the disclosure;

FIG. 7A illustrates a longitudinal cross-sectional view of a variation of the embodiment of the microelectronic device package of FIG. 2;

FIG. 7B illustrates a longitudinal cross-sectional view of a variation of the embodiment of the microelectronic device package of FIG. 5;

FIG. 7C illustrates a longitudinal cross-sectional view of a variation of the embodiment of the microelectronic device package of FIG. 6;

FIG. 8A illustrates a longitudinal cross-sectional view of a variation of the embodiment of the microelectronic device package of FIG. 2;

FIG. 8B illustrates a longitudinal cross-sectional view of a variation of the embodiment of the microelectronic device package of FIG. 5;

FIG. 8C illustrates a longitudinal cross-sectional view of a variation of the embodiment of the microelectronic device package of FIG. 6;

FIGS. 9 through 11 illustrate longitudinal cross-sectional views of variations of the embodiment of the microelectronic device package of FIG. 2;

FIG. 12 illustrates a flow chart representative of a method of assembly a microelectronic package in accordance with embodiments of the disclosure;

FIG. 13 illustrates a flow chart representative of a method of manufacturing a microelectronic package in accordance with embodiments of the disclosure; and

FIG. 14 is a schematic block diagram of an electronic system in accordance with one or more embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “configured” and “configuration” refers to a size, a shape, a material composition, a material distribution, orientation, and arrangement of at least one feature (e.g., one or more of at least one structure, at least one material, at least one region, at least one device) facilitating use of the at least one feature in a pre-determined way.

As used herein, the term “substantially” in reference to a given parameter means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, relational terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the drawings. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, the term “and/or” means and includes any and all combinations of one or more of the associated listed items.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbO₋ₓ₋), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbO₋ₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

Stacked microelectronic devices may include different types of semiconductor packages stacked on one another. For example, a stacked semiconductor package, such as a memory stack (e.g., NAND stack) may be stacked over another microclectronic device or semiconductor die, such as an application specific integrated circuit (ASIC) or a controller. Stacking the different types of semiconductor packages may reduce a surface area of the associated microelectronic device.

Embodiments of the disclosure include coupling additional electronic components, such as capacitors, resistors, inductors, among others to one or more of the stacked semiconductor packages that would conventionally be mounted to a substrate. Mounting the additional electronic components to one of the stacked semiconductor packages may further reduce a surface area of the stacked microelectronic device. Reducing a surface area of the microelectronic device may reduce space requirements for the microelectronic device, which may facilitate reducing a size of an associated electronic component (e.g., mobile phone, personal computer, or tablet computer) or increasing space for other components within the associated electronic component, which may provide greater power, memory, or benefits.

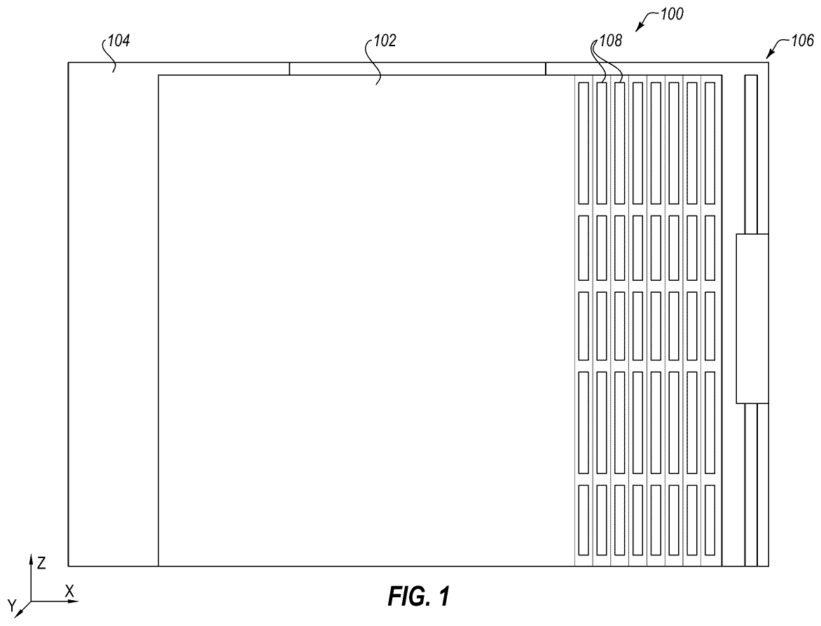

FIG. 1 illustrates a top-down view of a microelectronic device package 100. The microelectronic device package 100 may include a stacked semiconductor package 102 over a substrate 104. The stacked semiconductor package 102 may be formed from multiple semiconductor dies 108 stacked over one another. The semiconductor dies 108 may be individually and/or collectively coupled to the substrate 104 through electrical connections. The electrical connections between the stacked semiconductor package 102 and/or the associated semiconductor dies 108 may include direct attachments or direct connections (such as solder balls, columns, posts, or terminals) or wire bonds. Wire bond connections may extend between one or more of the semiconductor dies 108 of the stacked semiconductor package 102 and a connecting region 106 of the substrate 104.

The connecting region 106 may also include additional electronic components, such as capacitors, resistors, inductors, among others. The additional electronic components may be operatively coupled to the stacked semiconductor package 102 through internal circuitry in the substrate 104. Including the additional electronic components in the connecting region 106 may increase a surface area of the connecting region 106.

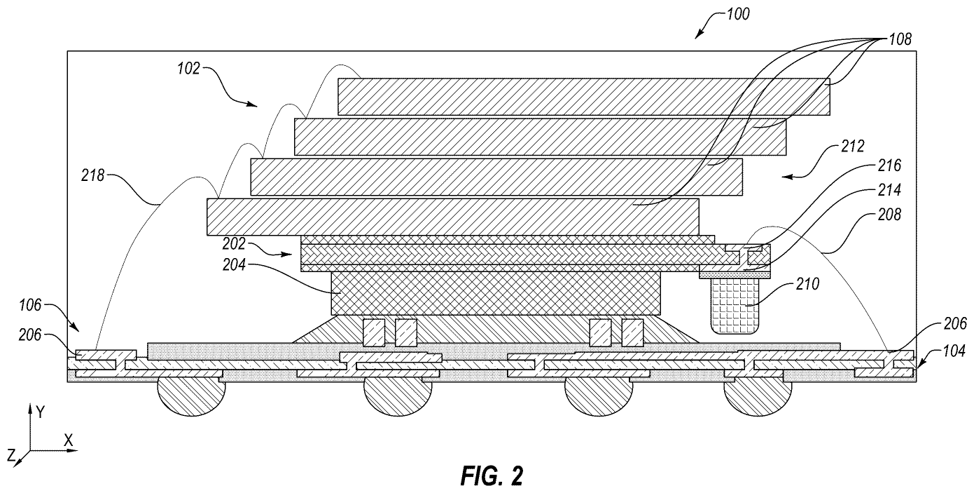

FIG. 2 illustrates a longitudinal cross-sectional view of the microelectronic device package 100. The stacked semiconductor package 102 may be positioned over the substrate 104. For example, the stacked semiconductor package 102 may be positioned over a microelectronic device 204 that is secured to the substrate 104, as illustrated in FIG. 2. In some embodiments, the stacked semiconductor package 102 may be secured directly to the microelectronic device 204. In another embodiment, an interposer 202 is positioned between the microelectronic device 204 and the stacked semiconductor package 102. An additional electronic component 210 (e.g., a capacitor, a resistor, an inductor) may be secured to the interposer 202. The interposer 202 may be formed from an insulative material configured to electrically isolate the additional electronic component 210 from the stacked semiconductor package 102 and/or the microelectronic device 204.

In some embodiments, the additional electronic component 210 is secured to a lower portion of the interposer 202, as illustrated in FIG. 2. For example, the interposer 202 may include a device contact pad 214 on the lower portion of the interposer 202 that may be electrically coupled to an upper contact pad 216 on an upper side of the interposer 202. In some embodiments, the upper contact pad 216 may be formed directly on the device contact pad 214. In other embodiments, a conductive via is formed between the device contact pad 214 and the upper contact pad 216.

The upper contact pad 216 may be coupled to a contact pad 206 on the substrate 104 through a wire bond 208. Thus, the additional electronic component 210 may be operatively coupled to the substrate 104 through the device contact pad 214, upper contact pad 216, and the wire bond 208. In some embodiments, the substrate 104 may include conductive paths defined within the substrate 104 that may operatively couple the additional electronic component 210 to one or more of the microelectronic device 204 and the stacked semiconductor package 102 through the contact pad 206. In other embodiments, the conductive paths in the substrate 104 may operatively couple the additional electronic component 210 to other electronic components and/or terminals for external connections.

The stacked semiconductor package 102 may be formed in a shingle stack as illustrated in FIG. 2. In embodiments where the stacked semiconductor package 102 are arranged in a shingle stack, the semiconductor dies 108 are arranged such that each semiconductor die 108 is laterally offset (e.g., in the X-direction) from the semiconductor die 108 immediately above or below the semiconductor die 108. Each semiconductor die 108 is laterally offset in a same lateral direction, such that the stacked semiconductor package 102 forms a step or shingle arrangement. The lateral offset of the adjacent semiconductor dies 108 leaves a portion of a top surface of each of the semiconductor dies 108 exposed. A wire bond 218 may be coupled between one or more of the exposed portions of the semiconductor dies 108 and a contact pad 206 in the connecting region 106 of the substrate 104. In some embodiments, a wire bond 218 is coupled directly to and extends between the exposed portion of each semiconductor die 108 and the contact pad 206 in the connecting region 106. In other embodiments, at least some pairs of the semiconductor dies 108 vertically neighboring one another have one or more wire bonds 218 coupled thereto and extending therebetween, as illustrated in FIG. 2, and at least one other of semiconductor dies 108 (e.g., a bottom semiconductor die 108 of the stacked semiconductor package 102) has at least one wire bond 218 coupled thereto that extends to and contacts the contact pad 206 in the connecting region 106.

The laterally offset semiconductor dies 108 of the stacked semiconductor package 102 may define an overhang 212 on a lateral side of the microelectronic device package 100 opposite the connecting region 106. The overhang 212 may extend over the additional electronic components 210 secured to the interposer 202. Thus, the interposer 202 and the additional electronic components 210 may be horizontally confined within a horizontal area of the microelectronic device package 100 defined by the stacked semiconductor package 102.

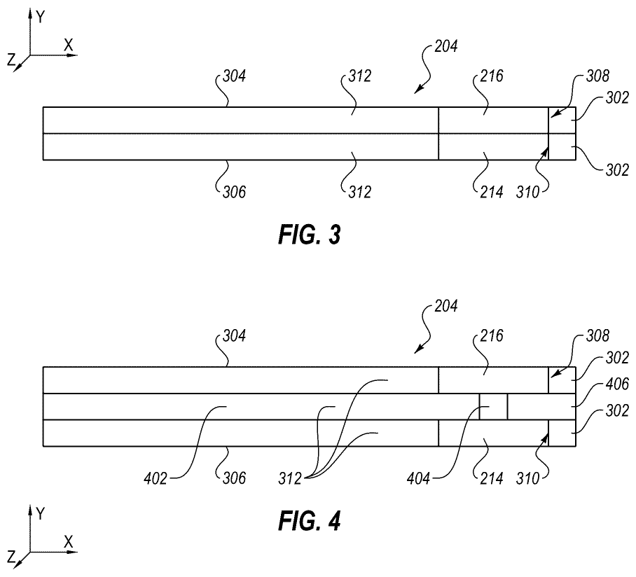

FIG. 3 illustrates an enlarged, longitudinal cross-sectional view of an embodiment of the interposer 202 of the microelectronic device package 100. The interposer 202 may include at least two vertically stacked structures. A device contact structure 306 may be positioned proximate the microelectronic device 204 (FIG. 2). The device contact structure 306 may include the device contact pad 214, as well as an insulative edge structure 302 and an insulative structure 312 horizontally bounding the device contact pad 214. The insulative edge structure 302 and the insulative structure 312 may be formed from an insulative material, such as dielectric oxide material, a titanium oxide (TiOₓ), a zirconium oxide (ZrOₓ), a tantalum oxide (TaOₓ), and a magnesium oxide (MgOₓ), at least one dielectric nitride material, at least one dielectric oxynitride material, at least one dielectric oxycarbide material, at least one hydrogenated dielectric oxycarbide material, and at least one dielectric carboxynitride material. The insulative edge structure 302 may be configured to substantially prevent shorts between the device contact pad 214 and other structures of the microelectronic device package 100 by substantially preventing the device contact pad 214 from contacting other structures of the microelectronic device package 100.

A stack contact structure 304 of the interposer 202 may be vertically offset from the device contact structure 306 and may be positioned proximate the stacked semiconductor package 102 (FIG. 2). The stack contact structure 304 may include the insulative structure 312 and an insulative edge structure 302 horizontally bounding the upper contact pad 216. The stack contact structure 304 may be positioned directly on the device contact structure 306. The upper contact pad 216 may be positioned over the device contact pad 214, such that an edge 308 of the upper contact pad 216 is substantially laterally aligned (e.g., in the X-direction) with an edge 310 of the device contact pad 214. The upper contact pad 216 may be in direct contact with the device contact pad 214, such that the upper contact pad 216 may be electrically connected to the device contact pad 214. The insulative structure 312 may cover an area of the interposer 202 that is configured to be attached to the stacked semiconductor package 102 (FIG. 2), such that the insulative structure 312 may be positioned between the conductive structures of the interposer 202 (e.g., the device contact pad 214 and the upper contact pad 216) and the stacked semiconductor package 102 (FIG. 2).

FIG. 4 illustrates an enlarged, longitudinal cross-sectional view of another embodiment of the interposer 202 of the microelectronic device package 100. The interposer 202 may include at least two vertically stacked structures, including the stack contact structure 304 and the device contact structure 306 previously described with reference to FIG. 3. The device contact structure 306 may be positioned proximate the microelectronic device 204 (FIG. 2), and includes the device contact pad 214, as well as the insulative edge structure 302 and the insulative structure 312 horizontally bounding the device contact pad 214. The stack contact structure 304 of the interposer 202 may be vertically offset from the device contact structure 306 and may be positioned proximate the stacked semiconductor package 102 (FIG. 2). The stack contact structure 304 includes the insulative structure 312 and the upper contact pad 216 with the additional insulative edge structure 302 on a side of the upper contact pad 216 opposite the insulative structure 312.

The interposer 202 may also include intermediate structures 402 positioned between the device contact structure 306 and the stack contact structure 304. The intermediate structures 402 may include an insulative structure 312 and an insulative edge structure 406 substantially surrounding a conductive connecting structure 404. The conductive connecting structure 404 may be positioned between the device contact pad 214 and the upper contact pad 216. The conductive connecting structure 404 may be formed of and include conductive material. The conductive connecting structure 404 may be configured to form an electrical connection between the device contact pad 214 and the upper contact pad 216. The conductive connecting structure 404 may have a horizontal surface area (e.g., in the X-Z Plane) less than or equal to a horizontal surface area of the device contact pad 214 and/or the upper contact pad 216. Thus, the insulative structure 312 of the intermediate structure 402 may cover a horizontal area equal to or greater than a horizontal area of the insulative structure 312 of the stack contact structure 304 or the device contact structure 306. The intermediate structures 402 may increase the insulative properties of the interposer 202 by increasing a thickness of insulative material.

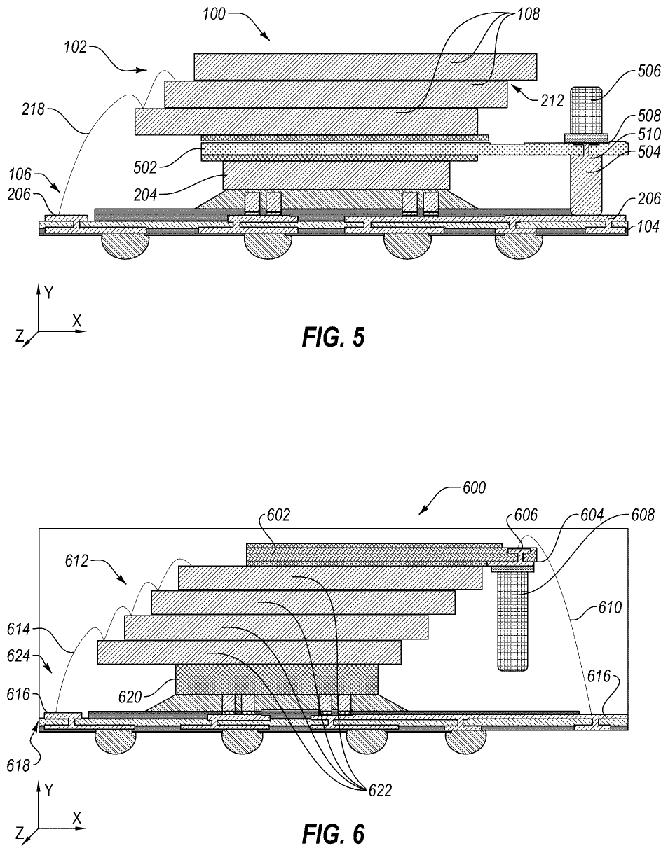

FIG. 5 illustrates an embodiment of a microelectronic device package 500, in accordance with additional embodiments of the disclosure. As shown in FIG. 5, the microelectronic device package 500 may have some features in common with the microelectronic device package 100 shown in FIG. 2. In FIG. 5, features of the microelectronic device package 500 substantially similar to those previously described in relation to the microelectronic device package 100 (FIG. 2) are provided with the same reference numbers previously used for FIG. 2. As shown in FIG. 5, the stacked semiconductor package 102 may be positioned over the microelectronic device 204 that is secured to the substrate 104. In some embodiments, an interposer 502 is positioned between the microelectronic device 204 and the stacked semiconductor package 102, as illustrated in FIG. 5. An additional electronic component 506 (e.g., a capacitor, resistor, inductor) may be secured to the interposer 502. The interposer 502 may be formed from an insulative material configured to electrically isolate the additional electronic component 506 from the stacked semiconductor package 102 and/or the microelectronic device 204.

In some embodiments, the additional electronic component 506 is secured to an upper portion of the interposer 502, as illustrated in FIG. 5. For example, the interposer 502 may include a device contact pad 508 on the upper portion of the interposer 502 that may be electrically coupled to a lower contact pad 510 on a lower side of the interposer 502. In some embodiments, the device contact pad 508 is formed directly on the lower contact pad 510. In other embodiments, a conductive via is formed between the device contact pad 508 and the lower contact pad 510.

The lower contact pad 510 may be coupled to a contact pad 206 on the substrate 104 through a direct contact structure 504 (e.g., a direct attachment or direct connection), such as a conductive pillar or conductive post extending between the contact pad 206 and the lower contact pad 510. Thus, the additional electronic component 506 may be operatively coupled to the substrate 104 through the device contact pad 508, lower contact pad 510, and the direct contact structure 504. In some embodiments, the substrate 104 includes conductive paths defined within the substrate 104 that operatively couple the additional electronic component 506 to one or more of the microelectronic device 204 and the stacked semiconductor package 102 through the contact pad 206. In other embodiments, the conductive paths in the substrate 104 operatively couple the additional electronic component 506 to other electronic components and/or terminals for external connections.

As described above, the stacked semiconductor package 102 may be formed in a shingle stack as illustrated in each of FIGS. 2 and 5. The semiconductor dies 108 arranged in a shingle stack the are arranged, such that each semiconductor die 108 is laterally offset (e.g., in the X-direction) from the semiconductor die 108 immediately above or below the semiconductor die 108, such that the stacked semiconductor package 102 forms a step or shingle arrangement. The lateral offset of the adjacent semiconductor dies 108 leaves a portion of a top surface of each of the semiconductor dies 108 exposed. A wire bond 218 may be coupled between one or more of the exposed portions of the semiconductor dies 108 and a contact pad 206 in the connecting region 106 of the substrate 104. In some embodiments, a wire bond 218 is coupled directly to and extends between the exposed portion of each semiconductor die 108 and the contact pad 206 in the connecting region 106. In other embodiments, at least some pairs of the semiconductor dies 108 vertically neighboring one another have one or more wire bonds 218 coupled thereto and extending therebetween, as illustrated in FIG. 5, and at least one other of semiconductor dies 108 (e.g., a bottom semiconductor die 108 of the stacked semiconductor package 102) has at least one wire bond 218 coupled thereto that extends to and contacts the contact pad 206 in the connecting region 106.

The interposer 502 may extend away from the interface between the stacked semiconductor package 102 and the microelectronic device 204 in a lateral direction opposite the connecting region 106. The extension of the interposer 502 may be sufficient to create clearance between the additional electronic component 506 and the semiconductor dies 108 of the stacked semiconductor package 102. For example, a smaller additional electronic component 506 may fit under an overhang 212 of the stacked semiconductor package 102, such that the interposer 502 may extend a lateral distance similar to the interposer 202 of FIG. 2. In other embodiments, the interposer 502 extends a greater distance in the lateral direction to accommodate a larger additional electronic component 506.

FIG. 6 illustrates a longitudinal cross-sectional view of a microelectronic device package 600, in accordance with embodiments of the disclosure. The stacked semiconductor package 612 may be positioned over a microelectronic device 620 that is secured to the substrate 618, as illustrated in FIG. 6. In some embodiments, the microelectronic device 620 and the stacked semiconductor package 612 are directly coupled to one another, as illustrated in FIG. 6. In other embodiments, an interposer, such as interposer 202, 502, (FIG. 2, FIG. 5) may be positioned between the microelectronic device 620 and the stacked semiconductor package 612.

An interposer structure 602 may be positioned over the stacked semiconductor package 612. For example, the interposer structure 602 may be secured to a top surface of a top semiconductor die 622 of the stacked semiconductor package 612. An additional electronic component 608 (e.g., a capacitor, a resistor, an inductor) may be secured to the interposer structure 602. The interposer structure 602 may be formed from an insulative material configured to electrically isolate the additional electronic component 608 from the stacked semiconductor package 612. The additional electronic component 608 may be suspended from a lower surface of the interposer structure 602, such that the additional electronic component 608 is suspended in a space between the interposer structure 602 and the substrate 618.

The additional electronic component 608 may be coupled to a lower contact pad 604 of the interposer structure 602 and a wire bond 610 may be coupled between an upper contact pad 606 of the interposer structure 602 and a contact pad 616 of the substrate 618. Thus, the additional electronic component 608 may be operatively coupled to the contact pad 616 of the substrate 618 through the additional electronic component 608, the upper contact pad 606 and the wire bond 610.

In some embodiments, the substrate 618 includes conductive paths defined within the substrate 618 that operatively couple the additional electronic component 608 to one or more of the microelectronic device 620 and the stacked semiconductor package 612 through the contact pad 616. In other embodiments, the conductive paths in the substrate 618 operatively couple the additional electronic component 608 to other electronic components and/or terminals for external connections.

As described above, the stacked semiconductor package 612 may be formed in a shingle stack as illustrated in FIG. 6. The semiconductor dies 622 may be arranged such that each semiconductor die 622 is laterally offset (e.g., in the X-direction) from the semiconductor die 622 immediately above or below the semiconductor die 622, such that the stacked semiconductor package 612 forms a step or shingle arrangement. The lateral offset of the adjacent semiconductor dies 622 leaves a portion of a top surface of each of the semiconductor dies 622 exposed. A wire bond 614 may be coupled between one or more of the exposed portions of the semiconductor dies 622 and a contact pad 616 in the connecting region 624 of the substrate 618. In some embodiments, a wire bond 614 is coupled directly between the exposed portion of each semiconductor die 622 and the contact pad 616 in the connecting region 624. In other embodiments, wire bonds 614 are coupled between adjacent semiconductor dies 622, as illustrated in FIG. 6, and a wire bond 614 is coupled between one of the semiconductor dies 622 (e.g., a bottom semiconductor die 622 of the stacked semiconductor package 612) and the contact pad 616 in the connecting region 624.

The interposer structure 602 may be coupled to a top surface of a top semiconductor die 622 of the semiconductor die 622 in a similar fashion to the other semiconductor dies 622, such that a portion of the interposer structure 602 extends away from the interface between the stacked semiconductor package 612 and the interposer structure 602 in a lateral direction opposite the connecting region 624. The extension of the interposer structure 602 may be sufficient to expose the lower contact pad 604 in an area beneath the interposer structure 602. The additional electronic component 608 may be suspended from the lower contact pad 604 in the space between the interposer structure 602 and the substrate 618. Positioning the interposer structure 602 above the stacked semiconductor package 612 may provide a greater volume of space between the interposer structure 602 and the substrate 618 to facilitate larger additional electronic components 608 without increasing a size or surface area of the microelectronic device package 600.

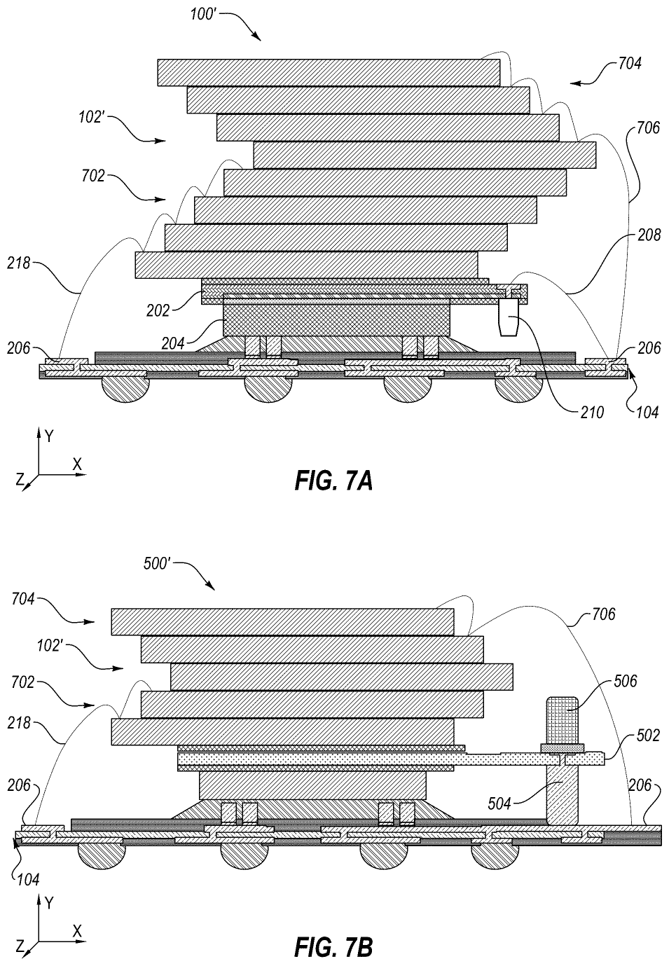

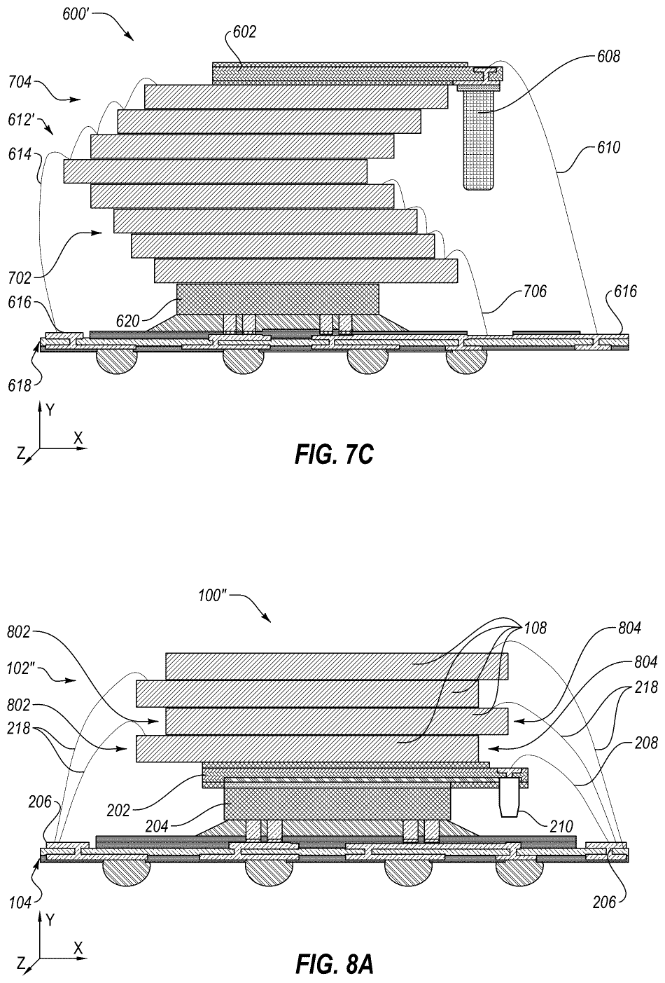

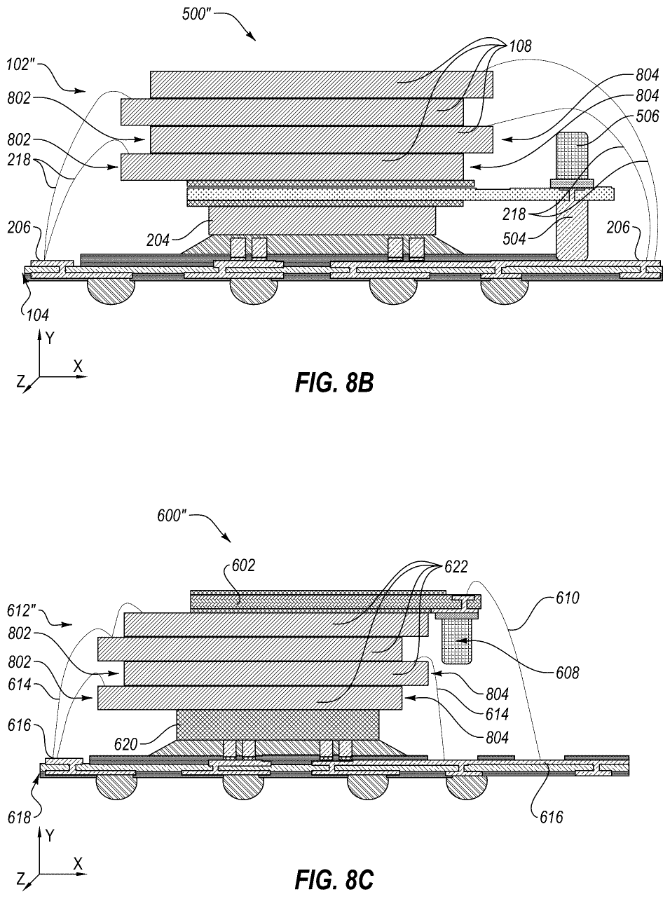

The microelectronic device packages 100, 500, and 600 described above with reference to FIGS. 2, 5, and 6, respectively, may be formed to have different configurations of the stacked semiconductor packages thereof. Such different configurations are described in further details below with reference to FIGS. 7A, 7B, 7C, 8A, 8B, and 8C. The additional embodiments of the disclosure described below with reference to FIGS. 7A, 7B, 7C, 8A, 8B, and 8C are illustrative and non-limiting.

FIG. 7A illustrates a longitudinal cross-sectional view of a microelectronic device package 100′ having all of the features of the microelectronic device package 100 previously described with reference FIG. 2 (such features retaining the same reference numbers as those employed in FIG. 2), but including a shingle die stack 702 (e.g., corresponding to the stacked semiconductor package 102 (FIG. 2)) and a reverse shingle die stack 704 positioned over the shingle die stack 702. The shingle die stack 702 and the reverse shingle die stack 704 may, in combination, form a single stacked semiconductor package 102′. As illustrated in FIG. 7A, the shingle die stack 702 may include the wire bonds 218 coupling the shingle die stack 702 to one contact pad 206 and the reverse shingle die stack 704 may include additional wire bonds 706 coupling the reverse shingle die stack 704 to another contact pad 206.

In some embodiments, the additional electronic component 210 coupled to the interposer 202 is coupled to the same contact pad 206 as one or more of the wire bonds 218, 706 from the stacked semiconductor package 102′ through a wire bond 208, as illustrated in FIG. 7A. In other embodiments, the wire bonds 218, 706 from the stacked semiconductor package 102′ are coupled to contact pads 206 that are in a different position than the contact pads 206 coupled to the wire bond 208 coupling the additional electronic component 210 to the substrate 104.

FIG. 7B illustrates a longitudinal cross-sectional view of a microelectronic device package 500′ having all of the features of the microelectronic device package 500 previously described with reference FIG. 5 (such features retaining the same reference numbers as those employed in FIG. 5), but including a shingle die stack 702 (e.g., corresponding to the stacked semiconductor package 102 (FIG. 5)) and a reverse shingle die stack 704 positioned over the shingle die stack 702. The shingle die stack 702 and the reverse shingle die stack 704 may, in combination, form a single stacked semiconductor package 102′. As illustrated in FIG. 7B, the shingle die stack 702 may include the wire bonds 218 coupling the shingle die stack 702 to one contact pad 206 and the reverse shingle die stack 704 may include additional wire bonds 706 coupling the reverse shingle die stack 704 to another contact pad 206.

In some embodiments, the additional electronic component 210 coupled to the interposer 202 is coupled to the same contact pad 206 as one or more of the wire bonds 218, 706 from the stacked semiconductor package 102′ through a direct contact structure 504, as illustrated in FIG. 7B. In other embodiments, the wire bonds 218, 706 from the stacked semiconductor package 102′ are coupled to contact pads 206 that are in a different position than the contact pads 206 coupled to the direct contact structure 504 coupling the additional electronic component 210 to the substrate 104.

FIG. 7C illustrates a longitudinal cross-sectional view of a microelectronic device package 600′ having all of the features of the microelectronic device package 600 previously described with reference FIG. 6 (such features retaining the same reference numbers as those employed in FIG. 6), but including a shingle die stack 702 (e.g., corresponding to the stacked semiconductor package 612 (FIG. 6)) and a reverse shingle die stack 704 interposed between the shingle die stack 702 and the microelectronic device 620. The shingle die stack 702 and the reverse shingle die stack 704 may, in combination, to form a stacked semiconductor package 612′. As illustrated in FIG. 7C, wire bonds 614 couple the shingle die stack 702 to one contact pad 616, and additional wire bonds 706 couple the reverse shingle die stack 704 to another contact pad 616. In some embodiments, contact pads 616 on both sides of the microelectronic device package 600′ may be coupled together through the substrate 618.

In some embodiments, a wire bond 610 extending between the interposer structure 602 and the substrate 618 is coupled to the same contact pad 616 as one or more of the wire bonds 614, 706 from the stacked semiconductor package 612. In other embodiments, the wire bonds 614, 706 from the stacked semiconductor package 612 are coupled to contact pads 616 that are in a different position than the contact pads 206 coupled to the wire bond 610 from the interposer structure 602.

FIG. 8A illustrates a longitudinal cross-sectional view of a microelectronic device package 100″ having all of the features previously described with reference FIG. 2 (such features retaining the same reference numbers as those employed in FIG. 2) but including a stacked semiconductor package 102″ including semiconductor dies 108 arranged in an alternating sequence of at least two horizontal positions. Horizontal ends (e.g., in the X-direction) of vertically neighboring (e.g., in the Z-direction) semiconductor dies 108 may be laterally offset from one another, with all of the semiconductor dies 108 individually being located at a first horizontal position within microelectronic device package 100″ or a second horizontal position within microelectronic device package 100″. The alternating lateral positions of the semiconductor dies 108 may facilitate a top surface of one of a first lateral end 802 and a second lateral end 804 being exposed, such that a wire bond 218 may be coupled to the associated semiconductor die 108. Thus, the wire bonds 218 may extend from opposing lateral ends 802, 804 of vertically neighboring semiconductor dies 108. The wire bonds 218 coupled to vertically neighboring semiconductor dies 108 may be connected to contact pads 206 of the substrate 104 on opposing sides of the microelectronic device package 100″.

In some embodiments, the additional electronic component 210 coupled to the interposer 202 is coupled to the same contact pad 206 as one or more of the wire bonds 218 from the stacked semiconductor package 102 through a wire bond 208 as illustrated in FIG. 8A. In other embodiments, the wire bonds 218 from the stacked semiconductor package 102 are coupled to contact pads 206 that are in a different position than the contact pads 206 coupled to the wire bond 208 extending from the interposer 202.

FIG. 8B illustrates a longitudinal cross-sectional view of a microelectronic device package 500″ having all of the features previously described with reference FIG. 5 (such features retaining the same reference numbers as those employed in FIG. 5) but including a stacked semiconductor package 102″ including semiconductor dies 108 arranged in an alternating sequence of at least two horizontal positions. Horizontal ends (e.g., in the X-direction) of vertically neighboring (e.g., in the Z-direction) semiconductor dies 108 may be laterally offset from one another, with all of the semiconductor dies 108 individually being located at a first horizontal position within microelectronic device package 100″ or a second horizontal position within microelectronic device package 100″. The alternating lateral positions of the semiconductor dies 108 may facilitate a top surface of one of a first lateral end 802 and a second lateral end 804 being exposed, such that a wire bond 218 may be coupled to the associated semiconductor die 108. Thus, the wire bonds 218 may extend from opposing lateral ends 802, 804 of vertically neighboring semiconductor dies 108. The wire bonds 218 coupled to vertically neighboring semiconductor dies 108 may be connected to contact pads 206 of the substrate 104 on opposing sides of the microelectronic device package 100″.

In some embodiments, the additional electronic component 210 coupled to the interposer 202 is coupled to the same contact pad 206 as one or more of the wire bonds 218 from the stacked semiconductor package 102″ through a direct contact structure 504, as illustrated in FIG. 8B. In other embodiments, the wire bonds 218 from the stacked semiconductor package 102″ are coupled to contact pads 206 that are in a different position than the contact pads 206 coupled to the direct contact structure 504 coupling the additional electronic component 210 to the substrate 104.

FIG. 8C illustrates a longitudinal cross-sectional view of a microelectronic device package 600″ having all of the features of the microelectronic device package 600 previously described with reference FIG. 6 (such features retaining the same reference numbers as those employed in FIG. 6) but including a stacked semiconductor package 612″ including semiconductor dies 622 arranged in an alternating sequence of at least two horizontal positions. Horizontal ends (e.g., in the X-direction) of vertically neighboring (e.g., in the Z-direction) semiconductor dies 622 may be laterally offset from one another, with all of the semiconductor dies 622 individually being located at a first horizontal position within microelectronic device package 600″ or a second horizontal position within microelectronic device package 600″. The alternating lateral positions may facilitate a top surface of one of a first lateral end 802 and a second lateral end 804 being exposed, such that a wire bond 614 may be coupled to the associated semiconductor dies 622. Thus, the wire bonds 614 may extend from opposing lateral ends 802, 804 of vertically neighboring semiconductor dies 622. The wire bonds 614 from vertically neighboring semiconductor dies 622 may also be connected to contact pads 616 of the substrate 618 on opposing sides of the microelectronic device package 600″.

In some embodiments, a wire bond 610 extending between the interposer structure 602 and the substrate 618 is coupled to the same contact pad 616 as one or more of the wire bonds 614 from the stacked semiconductor package 612. In other embodiments, the wire bonds 614 from the stacked semiconductor package 612 are coupled to contact pads 616 that are in a different position than the contact pads 616 coupled to the wire bond 610 from the additional electronic component 608 suspended form the interposer structure 602, as illustrated in FIG. 8C.

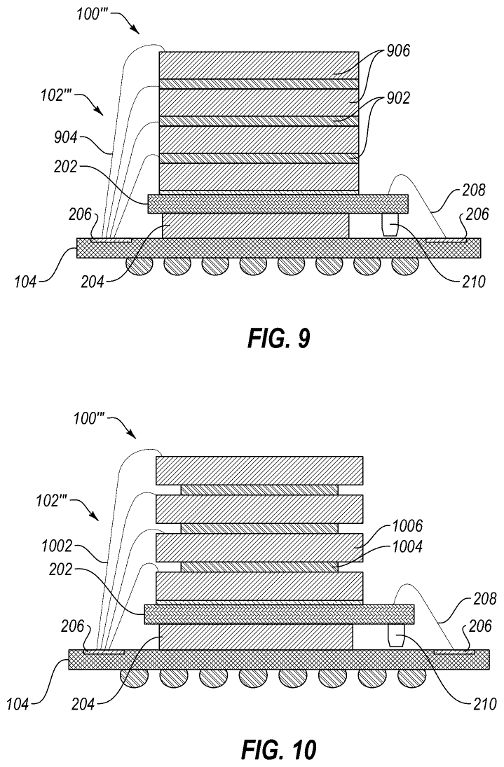

In additional embodiments, the dies of the stacked semiconductor package 102 may be positioned, such that there is substantially no lateral offset between vertically neighboring dies. FIGS. 9 through 11 illustrate different embodiments of stacked semiconductor packages 102 where the adjacent dies are not substantially laterally offset from one another. Each of FIGS. 9 through 11 are illustrated as alternate configurations for the microelectronic device package 100 previously described with reference to FIG. 1, however, it is understood that other types of microelectronic package configurations, such as the various configurations for the microelectronic device packages 500, 600, previously described with reference to FIGS. 5, 6, 7B, 7C, 8B, and 8C, can also be modified in accordance with the various modifications to the microelectronic device package 100 described hereinbelow with reference to FIGS. 9 through 11.

FIG. 9 illustrates an alternate configuration for the microelectronic device package 100 wherein the stacked semiconductor package 102′″ is formed from multiple dies 906 that are substantially laterally aligned with vertically neighboring dies 906 in the stacked semiconductor package 102. The stacked semiconductor package 102′″ also includes an insulative film 902 positioned between each adjacent die 906 of the stacked semiconductor package 102′″. The insulative film 902 may define a space between each adjacent die 906, which provides a space through which a wire bond 904 may contact a surface of one die 906 of the stacked semiconductor package 102′″ without contacting an adjacent die 906 of the stacked semiconductor package 102′″. As illustrated in FIG. 9, the stacked semiconductor package 102′″ may include wire bonds 904 coupling each die 906 of the stacked semiconductor package 102′″ to a first contact pad 206. The insulative film 902 may substantially encapsulate the wire bonds 904, such that the wire bonds 904 do not inadvertently contact an adjacent die 906 of the stacked semiconductor package 102. The additional electronic component 210 may be coupled to a second contact pad 206 on an opposite side of the microelectronic device package 100 through a wire bond 208 extending between the interposer 202 and the contact pad 206. As described above, in some embodiments the contact pads 206 on both sides of the microelectronic device package 100′″ may be contact pads 206, which may each be coupled together through the substrate 104.

FIG. 10 illustrates an alternate configuration for the microelectronic device package 100, wherein the stacked semiconductor package 102″″ is formed from multiple dies 1006 that are substantially laterally aligned with vertically neighboring dies 1006 in the stacked semiconductor package 102″″. The stacked semiconductor package 102″″ also includes a spacer 1004 positioned between each adjacent die 1006 of the stacked semiconductor package 102″″. The spacer 1004 may be formed from an insulative material and may define a space between each adjacent die 1006, which provides a space through which a wire bond 1002 may contact a surface of one die 1006 of the stacked semiconductor package 102″″ without contacting an adjacent die 1006 of the stacked semiconductor package 102″″. As illustrated in FIG. 10, the stacked semiconductor package 102″″ may include wire bonds 1002 coupling each die 1006 of the stacked semiconductor package 102″″ to a first contact pad 206. The additional electronic component 210 may be coupled to a second contact pad 206 on an opposite side of the microelectronic device package 100″″ through a wire bond 208 extending between the interposer 202 and the contact pad 206. As described above, in some embodiments, the contact pads 206 on both sides of the microelectronic device package 100″″ may be contact pads 206, which may each be coupled together through the substrate 104.

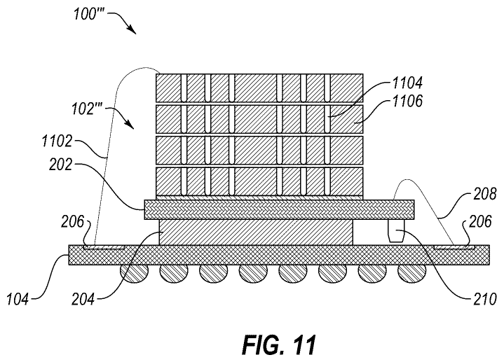

FIG. 11 illustrates an alternative configuration for the microelectronic device package 100, wherein the stacked semiconductor package 102′″″ is formed from multiple dies 1106 that are substantially laterally aligned with vertically neighboring dies 1106 in the stacked semiconductor package 102′″″. The dies 1106 of the stacked semiconductor package 102′″″ may be coupled together through one or more through silicon vias 1104 (TSVs), extending through each of the dies 1106. The TSVs 1104 may electrically couple the adjacent dies 1106 to one another, similar to the wire bonds 218 of FIG. 2, such that a wire bond 1102 may extend from a top die 1106 of the stacked semiconductor package 102′″″, to operatively couple all of the dies 1106 in the stacked semiconductor package 102′″″ to the contact pad 206. The additional electronic component 210 may be coupled to a second contact pad 206 on an opposite side of the microelectronic device package 100′″″ through a wire bond 208 extending between the interposer 202 and the contact pad 206. As described above, in some embodiments the contact pads 206 on both sides of the microelectronic device package 100′″″ may be contact pads 206, which may each be coupled together through the substrate 104.

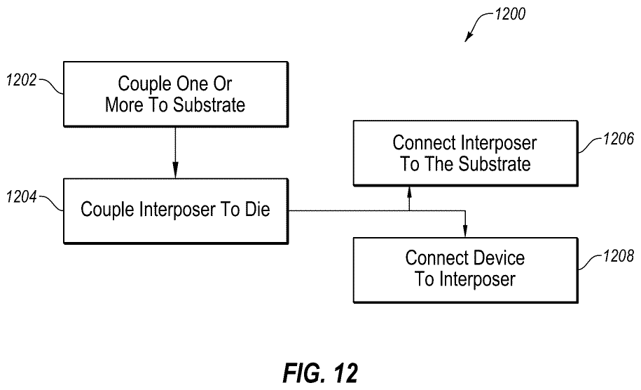

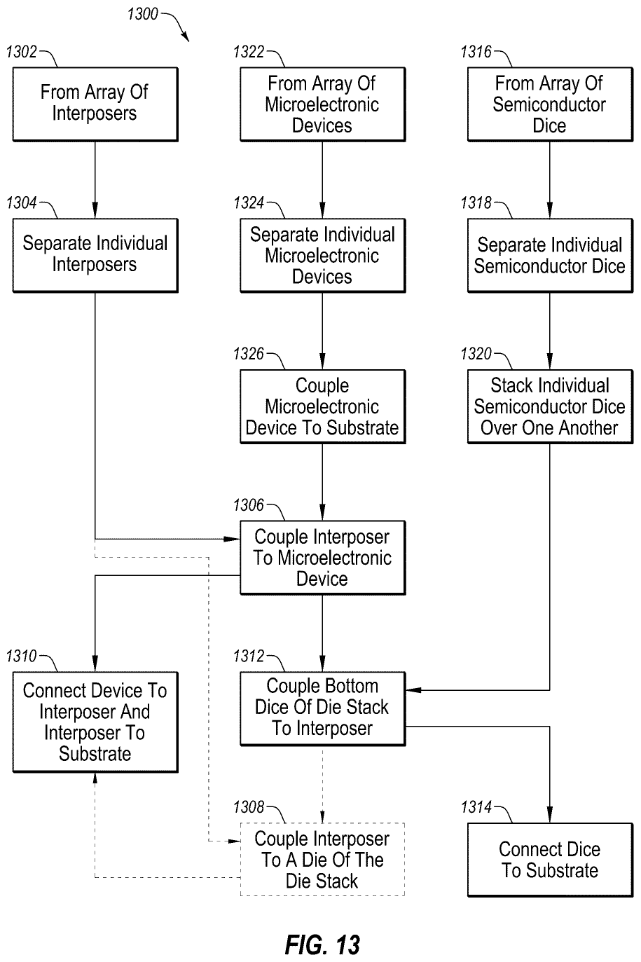

FIG. 12 illustrates a flow chart of a method of assembling 1200 a microelectronic device package (e.g., the microelectronic device packages 100, 100′, 100″, 100′″, 100″″, 100′″″, 500, 500′, 500″, 600, 600′, 600″ described above) of the disclosure. For the purpose of the method of assembling 1200, the processes of manufacturing the individual parts, such as the semiconductor dies, microelectronic devices, interposers, and so on, are not described. The manufacturing processes are described in greater detail below with respect to FIG. 13.

A microelectronic device, such as a semiconductor die, integrated circuit, controller, and so on, may be coupled to a substrate, such as a printed circuit board, in act 1202. The substrate and the microelectronic device may include complementary connection points, such as posts, pins, solder balls, and/or solder pads. The complementary connection points may include electrical connections through the substrate, such as receiving pads, transmitting pads, power pads, and/or ground pads. The different connection points may be operably coupled to different circuits within the substrate that may transmit electrical signals to other components connected to the substrate. In some embodiments, the microelectronic device is further secured to the substrate through additional material, such as a molding compound.

After the microelectronic device is connected to the substrate, an interposer may be coupled to a surface of the microelectronic device in act 1204. The interposer may be coupled to a surface of the microelectronic device on an opposite side of the microelectronic device opposite the substrate. In some embodiments, the interposer may be coupled to the surface of the microelectronic device though an adhesive (e.g., epoxy or die attach film). In other embodiments, the interposer may be coupled to the surface of the microelectronic device through a conductive connection, such as solder, solder bumps, conductive pads, or pins.

The conductive structure of the interposer may then be coupled to the substrate in act 1206. As described above, the conductive structure may include a conductive pad on an upper surface and a lower surface of the interposer. The conductive pad may be coupled to the substrate through a wire bond coupled between the upper conductive pad of the interposer and a conductive pad of the substrate. In other embodiments, the lower conductive pad of the interposer is coupled directly to a conductive pad on the substrate through a direct attachment point (e.g., a direct contact structure, a direct attachment, or a direct connection), such as a post extending from the substrate, such that the conductive structure of the interposer may rest against the direct attachment point and be secured thereto through a soldering process or with a conductive adhesive material.

An additional electronic component, such as a capacitor, inductor, or resistor, may be coupled to one of the upper or lower conductive pads of the interposer in act 1208. The additional electronic component may be coupled to the respective conductive pad on a side of the interposer opposite the connection between the interposer and the substrate. For example, the additional electronic component may be suspended from a lower conductive pad and an upper conductive pad may be coupled to the substrate through a wire bond in act 1206, as described above. In another example, the electronic component may be coupled to the upper conductive pad and the opposite lower conductive pad may be coupled to the substrate through a direct attachment point in act 1206, as described above. The additional electronic component may be coupled to the respective conductive pad through a conductive attachment, such as pin, terminal, solder, or conductive adhesive.

FIG. 13 illustrates a flow chart representative of a method of manufacturing 1300 a microelectronic device package (e.g., the microelectronic device packages 100, 100′, 100″, 100′″, 100″″, 100′″″, 500, 500′, 500″, 600, 600′, 600″ described above) of the disclosure. One or more (e.g., each) of the components of the final microelectronic device package may be formed individually and then assembled to form the microelectronic device package. Therefore, the different forming processes may operate in parallel and/or do not have any specific order in which they are completed and may be completed separately and then provided to an assembly process. Once the individual components are formed they may then be assembled in the process described above in FIG. 12.

Each of the components may be formed in arrays formed on a substrate, such as a semiconductor wafer through build up processes, such as deposition, or sputtering, material removal processes, such as etching (e.g., wet etch or dry etch), lithography (e.g., photolithography, optical lithography, or UV lithography), and filling processes. Once the array of components is formed, the array may be separated into individual components through a separation process, such as a dicing process.

An array of microelectronic devices may be formed on a substrate in act 1322. As described above, the microelectronic devices may be a semiconductor die, integrated circuit, or controller. The microelectronic devices may be formed by building up layers of dielectric material over a substrate. Portions of the semiconductor material may then be selectively removed. For example, masks may be used to expose some portions to a removal process while protecting other portions from the removal process. In other examples, a material removal process which selectively removes some types of materials while not removing other types of materials, such as due to differences in a material removal rate for the two different types of materials due to different reactivity between the two different types of material and the material removal process. A backfill operation may then be used to fill in regions where material was removed with a conductive material, to form circuitry and/or other components within the microelectronic devices. These processes may be repeated to form multiple stacked structures and circuitry in the different structures of the microelectronic device. In other cases, multiple stacked structures of insulative material may be formed before the array of microelectronic devices is subject to a selective material removal process.

After the array of microelectronic devices is formed, the substrate may be separated into individual dies or microelectronic devices along scribe lines defined between the multiple microelectronic devices in the array in act 1324. The substrate may be separated through dicing processes. For example, the substrate may be separated through mechanical dicing utilizing a grinding or cutting wheel to cut through the substrate along the scribe lines. In another example, the substrate may be separated through a laser dicing process using a laser to melt the substrate along the scribe lines. In another example, the substrate may be separated through stealth dicing by creating a modified or weakened zone along the scribe lines and fracturing the substrate along the scribe lines using the weakened region in the modified zone to guide the fractures.

An array of semiconductor dies may be formed on another substrate, such as a semiconductor wafer in act 1316. The array of semiconductor dies may formed in a similar fashion as the array of microelectronic devices. For example, the array of semiconductor dies may be formed through one or more material buildup processes, one or more selective material removal processes, and one or more back filling processes. As described above, these processes may alternate to form stacked structures or may be performed in other orders, such as building up multiple insulative structures before selectively removing some of the insulative structures in a subsequent process.

The array of semiconductor dies may then be separated into individual semiconductor dies in act 1318. As described above, the substrate may be separated through dicing processes, such as mechanical dicing processes, laser dicing processes, and/or stealth dicing processes. The individual dies may then be stacked over one another to form a die stack in act 1320. The individual dies may be stacked in a manner that exposes a portion of the top surface of each die on one or more lateral ends of each die. The exposed portion of the top surface of each die may be used to secure a wire bond to each of the semiconductor dies in the stack in a future step. In some cases, the exposed portion of the top surface of each die may be on the same lateral end of each die in the stack, such as a shingle stack or reverse shingle stack as described and illustrated in FIGS. 2, 5, 6, 7A and 7B. In other embodiments one or more of the dies in the die stack may be offset in an opposite direction such that the portion of the top surface of the associated die may be on an opposite lateral end of the die from an adjacent die in the die stack, such as the examples illustrated in FIGS. 8A and 8B. In other embodiments, the dies in the die stack may be substantially aligned with vertically neighboring dies in the dies stack and may be arranged with spacers, films, or direct contacts (e.g., TSVs) to facilitate connecting the dies in the die stack to the substrate, such as the examples illustrated in FIGS. 9 through 11. Other types or configurations of die stacks may similarly be built without limitation.

An array of interposers may be formed over a substrate in act 1302. The array of interposers may be formed in a similar manner to that described above in acts 1316 and 1322. In some cases, the array of interposers may be formed by forming a first insulative structure, selectively removing a portion of the first insulative structure, filling in the region where the insulative material of the insulative structure was removed with a conductive material to form the conducting structure. Another insulative structure may then be formed over the first structure. In some cases additional material removal and back fill processes may be formed on the additional insulative structures. In other cases, the additional insulative structures may be formed as a single insulative structure over the first structure. After the array of interposers is formed, the array may then be separated into individual interposers in act 1304. As described above, the substrate may be separated through dicing processes, such as mechanical dicing processes, laser dicing processes, and/or stealth dicing processes.

A microelectronic device formed as described above, may be provided for an assembly process. The microelectronic device may be coupled to a substrate, such as a printed circuit board, in act 1326. The substrate and the microelectronic device may include complementary connection points, such as posts, pins, solder balls, or solder pads. The complementary connection points may include electrical connections through the substrate, such as receiving pads, transmitting pads, power pads, or ground pads. The different connection points may be operably coupled to different circuits within the substrate that may transmit electrical signals to other components connected to the substrate. In some embodiments, the microelectronic device may be further secured to the substrate through an additional materials, such as a molding compound.

After the microelectronic device is connected to the substrate, an interposer formed as described above, may be provided and coupled to a surface of the microelectronic device in act 1306. The interposer may be coupled to a surface of the microelectronic device on a side of the microelectronic device opposite the substrate.

A die stack formed as described above, may be provided and coupled to a top surface of the interposer in act 1312. The die stack may be coupled to a top insulative structure of the interposer. The die stack may be secured to the interposer through an adhesive material, such as a die attach film, tape, or epoxy, positioned between a bottom surface of a bottom die of the die stack and the insulative structure of the interposer.

In some embodiments, the die stack may be directly coupled to the top surface of the microelectronic device. For example, in some embodiments, an interposer is not positioned between the microelectronic device and the die stack, such that act 1306 may be skipped. In some embodiments, the interposer may be coupled to a top surface of a die of the die stack in act 1308 rather than being coupled to the top surface of the microelectronic device in act 1306. As described above, positioning the interposer over the dies of the die stack may facilitate an increased volume of space for larger additional electronic devices.

The die stack may be coupled to the substrate in act 1314. The die stack may be coupled to the substrate through wire bond connections between the dies of the die stack and contact pads of the substrate. The contact pads may include ground pads, power pads, transmitting pads, and/or receiving pads. As described above, each die of the die stack may be arranged such that a portion of a top surface of each die is exposed (e.g., not covered or in contact with an adjacent die in the die stack). The wire bonds may be coupled to the exposed portion of each die in the die stack. In some cases, the wire bond may extend between two adjacent dies in the die stack. In other embodiments, the wire bond may extend from the surface of the die to a conductive pad on the substrate. At least one of the wire bonds may extend from a surface of at least one of the dies and a ground pad of the substrate. The grounding wire bond may be configured to drain an accumulated electrical charge from the outer surface of the die stack. Other wire bonds may be configured to transmit or receive signals to/from the die stack. For example, the wire bonds may be coupled to contact pads, which may be operably coupled to transmit or receive pads associated with the microelectronic device, such that the substrate may facilitate the transmission of electrical signals between the die stack and the microelectronic device.

After the interposer is coupled to the microelectronic device package in act 1306 and/or act 1308, the conductive structure of the interposer may be coupled to an additional electronic component and to the substrate in act 1310. As described above, the additional electronic component and the substrate may be coupled to the interposer through conductive pads on the upper and lower sides of the interposer. The additional electronic component and the substrate may be coupled to opposing sides of the interposer, such that the additional electronic component is electrically coupled to the substrate through the conductive structure of the interposer.

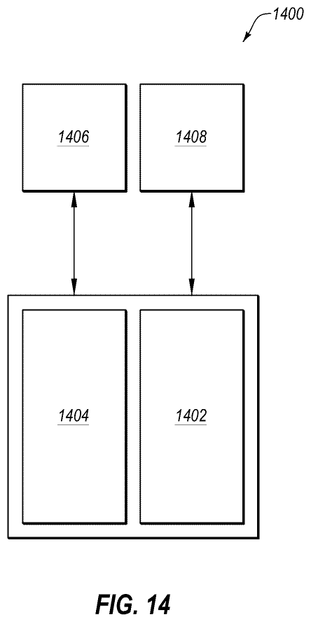

Microelectronic devices (e.g., the microelectronic device packages 100, 100′, 100″, 100′″, 100″″, 100′″″, 500, 500′, 500″, 600, 600′, 600″ including the stacked structures of the disclosure) may be included in embodiments of electronic systems of the disclosure. For example, FIG. 14 is a block diagram of an electronic system 1400, in accordance with embodiments of the disclosure. The electronic system 1400 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, or a navigation device. The electronic system 1400 includes at least one memory device 1402. The memory device 1402 may include, for example, an embodiment of a microelectronic device package previously described herein (e.g., the microelectronic device packages 100, 100′, 100″, 100′″, 100″″, 100′″″, 500, 500′, 500″, 600, 600′, 600″ previously described with reference to FIGS. 1 through 8B).

The electronic system 1400 may further include at least one electronic signal processor device 1404 (often referred to as a “microprocessor”). The electronic signal processor device 1404 may, optionally, include an embodiment of one or more of a microelectronic device and a microelectronic device structure previously described herein. The electronic system 1400 may further include one or more input devices 1406 for inputting information into the electronic system 1400 by a user, such as, for example, a mouse or other pointing device, a keyboard, a touchpad, a button, or a control panel. The electronic system 1400 may further include one or more output devices 1408 for outputting information (e.g., visual or audio output) to a user such as, for example, a monitor, a display, a printer, an audio output jack, or a speaker. In some embodiments, the input device 1406 and the output device 1408 may comprise a single touchscreen device that can be used both to input information to the electronic system 1400 and to output visual information to a user. The input device 1406 and the output device 1408 may communicate electrically with one or more of the memory device 1402 and the electronic signal processor device 1404.

Thus, embodiments of the disclosure include a microelectronic device package. The microelectronic device package includes a stack of semiconductor dies positioned over a substrate. The microelectronic device package further includes an interposer structure coupled to the stack of semiconductor dies. The microelectronic device package further includes an electronic component directly coupled to the interposer structure and electrically coupled to the substrate through an electrical connection between the interposer structure and the substrate.

Another embodiment of the disclosure includes an electronic system. The system includes an input device, an output device, a processor device operably coupled to the input device and the output device, and a memory device operably coupled to the processor device. The memory device includes at least one semiconductor die secured to a substrate. The memory device further includes an interposer structure including a conductive structure positioned over the at least one semiconductor die. The memory device also includes an additional electronic component secured to the interposer structure, the additional electronic component operably coupled to the substrate through the conductive structure of the interposer.

Another embodiment of the disclosure includes a method of assembling a stacked microelectronic device package. The method includes providing a microelectronic device. The method further includes coupling the microelectronic device to a substrate. The method also includes providing an interposer including a conductive structure. The method further includes positioning the interposer over the microelectronic device. The method also includes securing an additional electronic component to the conductive structure of the interposer. The method further includes connecting the conductive structure of the interposer to a contact pad of the substrate.

Embodiments of the disclosure may reduce a footprint area of the associated microelectronic device packages. Reducing footprint areas of the microelectronic device packages may reduce the space requirements in an associated electronic device, which may provide additional space for other components and/or facilitate a reduction in size of the associated electronic device.

The embodiments of the disclosure described above and illustrated in the accompanying drawing figures do not limit the scope of the invention, since these embodiments are merely examples of embodiments of the invention, which is defined by the appended claims and their legal equivalents. Any equivalent embodiments are intended to be within the scope of this disclosure. Indeed, various modifications of the present disclosure, in addition to those shown and described herein, such as alternative useful combinations of the elements described, may become apparent to those skilled in the art from the description. Such modifications and embodiments are also intended to fall within the scope of the appended claims and their legal equivalents.

What is claimed is:

1. A microelectronic device package comprising:
a stack of semiconductor dies positioned over a substrate;
an interposer structure coupled to the stack of semiconductor dies; and
an electronic component directly coupled to the interposer structure and electrically coupled to the substrate through an electrical connection between the interposer structure and the substrate.

2. The microelectronic device package of claim 1, wherein the electrical connection comprises a wire bond.

3. The microelectronic device package of claim 1, wherein the electrical connection comprises a direct connection.

4. The microelectronic device package of claim 1, wherein the interposer structure is positioned between the stack of semiconductor dies and a microelectronic device.

5. The microelectronic device package of claim 1, wherein the interposer structure is positioned over the stack of semiconductor dies.

6. The microelectronic device package of claim 1, wherein the stack of semiconductor dies defines an overhang region between the stack of semiconductor dies and the substrate.

7. The microelectronic device package of claim 6, wherein the electronic component is positioned within the overhang region.

8. The microelectronic device package of claim 1, wherein the electronic component is suspended from the interposer structure.

9. The microelectronic device package of claim 1, wherein the electronic component is on an upper surface of the interposer structure.

10. The microelectronic device package of claim 1, wherein the electronic component comprises one or more of a capacitor, an inductor, and a resistor.

11. An electronic system, comprising:
an input device;
an output device;
a processor device operably coupled to the input device and the output device; and
a memory device operably coupled to the processor device and comprising:
at least one semiconductor die secured to a substrate;
an interposer including a conductive structure positioned over the at least one semiconductor die; and
an additional electronic component secured to the interposer, the additional electronic component operably coupled to the substrate through the conductive structure of the interposer.

12. The electronic system of claim 11, wherein the conductive structure of the interposer is coupled to the substrate through a wire bond.

13. The electronic system of claim 11, wherein the conductive structure of the interposer is coupled to the substrate through a direct attachment point.

14. The electronic system of claim 11, wherein the conductive structure includes a first contact pad in a first surface of the interposer and a second contact pad in a second surface of the interposer opposite the first surface.

15. The electronic system of claim 14, wherein the additional electronic component is secured to the first contact pad and the substrate is coupled to the second contact pad.

16. A method of assembling a stacked microelectronic device package, the method comprising:
providing a microelectronic device;
coupling the microelectronic device to a substrate;
providing an interposer including a conductive structure;
positioning the interposer over the microelectronic device;
securing an additional electronic component to the conductive structure of the interposer; and
connecting the conductive structure of the interposer to a contact pad of the substrate.

17. The method of claim 16, wherein securing the additional electronic component to the conductive structure including securing the additional electronic component to the conductive structure of the interposer on a first side of the interposer.

18. The method of claim 17, wherein connecting the conductive structure of the interposer to the contact pad of the substrate includes extending a conductive element between the contact pad of the substrate and the conductive structure of the interposer on a second side of the interposer opposite the first side of the interposer.

19. The method of claim 18, wherein extending the conductive element between the contact pad of the substrate and the conductive structure includes extending a wire bond between the contact pad of the substrate and the conductive structure.

20. The method of claim 18, wherein extending the conductive element between the contact pad of the substrate and the conductive structure includes extending a conductive post between the contact pad of the substrate and the conductive structure.
